(19) United States
(12) Patent Application Publication
(10) Pub. No.: US 2026/0149076 A1
(43) Pub. Date: May 28, 2026

(54) Battery Heating Apparatus and Operating Method Thereof

(71) Applicant: LG Energy Solution, Ltd., Seoul (KR)

(72) Inventor: Chi Ho Moon, Daejeon (KR)

(73) Assignee: LG Energy Solution, Ltd., Seoul (KR)

(21) Appl. No.: 19/120,011

(22) PCT Filed: Jul. 19, 2023
(86) PCT No.: PCT/KR2023/010401

§ 371 Date: Apr. 10, 2025

(30) Foreign Application Priority Data
Oct. 14, 2022 (KR) 10-2022-0132751

(51) Int. Cl. H01M 10/615; G01R 31/3842; G01R 31/396; H01M 10/44; H01M 10/48

(52) U.S. Cl. CPC H01M 10/615; G01R 31/3842; G01R 31/396; H01M 10/443; H01M 10/486

(57) ABSTRACT

A battery heating apparatus according to an embodiment disclosed herein includes one or more sensors configured to measure at least one of a voltage, a current, or a temperature of the battery, a controller-configured to determine a first charge power of the battery based on a calculated state of charge (SoC) of the battery and a maximum charge power of a charger to charge the battery, and determine whether to heat the battery based on the measured temperature and the first charge power, and a heater configured to heat the battery in response to determining to heat the battery.

### CROSS-REFERENCE TO RELATED APPLICATION

The present application is a national phase entry under 35 U.S.C. § 371 of International Application No. PCT/KR 2023/010401 filed Jul. 19, 2023, which claims priority from Korean Patent Application No. 10-2022-0132751 filed in the Korean Intellectual Property Office on Oct. 14, 2022, the entire contents of which are incorporated herein by reference.

### TECHNICAL FIELD

Embodiments disclosed herein relate to a battery heating apparatus and an operating method thereof.

### Background Art

Recently, research and development of secondary batteries have been actively performed. Herein, the secondary batteries, which are chargeable/dischargeable batteries, may include all of conventional nickel (Ni)/cadmium (Cd) batteries, Ni/metal hydride (MH) batteries, etc., and recent lithium-ion batteries. Among the secondary batteries, a lithium-ion battery has a much higher energy density than those of the conventional Ni/Cd batteries, Ni/MH batteries, etc. Moreover, the lithium-ion battery may be manufactured to be small and lightweight, such that the lithium-ion battery has been used as a power source of mobile devices, and recently, a use range thereof has been extended to power sources for electric vehicles, attracting attention as next-generation energy storage media.

Batteries undergo different chemical changes therein according to temperatures during charge. When charge is performed in a low-temperature state or a high-temperature state of a battery, performance of the battery may be degraded or a function of the battery may be permanently damaged. For example, during charge of a battery having a temperature being a specific temperature or less, a swelling phenomenon may occur in which the battery swells and thus a function thereof is damaged. To solve this problem, a system has been used to heat a battery when a temperature of the battery is a specific temperature or less before or during charge of the battery.

### SUMMARY

### Technical Problem

In relation to a battery heating system, conventionally, as a preset heating function is activated simply under a condition that a temperature of a battery is a certain temperature or less, without considering specifications and a state of charge of a battery, specifications of a charger, etc., unnecessary power consumption occurs.

Embodiments disclosed herein aim to provide a battery heating apparatus and an operating method thereof in which power consumption caused by unnecessary battery heating may be reduced by determining whether to heat a battery based on various parameters (e.g., a state of charge and a temperature of the battery and a maximum charge power of a charger).

Technical problems of the embodiments disclosed herein are not limited to the above-described technical problems, and other unmentioned technical problems would be clearly understood by one of ordinary skill in the art from the following description.

### Technical Solution

A battery heating apparatus according to an embodiment disclosed herein includes one or more sensors configured to measure at least one of a voltage, a current, or a temperature of the battery, a controller configured to determine a first charge power of the battery based on a calculated state of charge (SoC) of the battery and a maximum charge power of a charger to charge the battery, and determine whether to heat the battery based on the measured temperature and the first charge power, and a heater configured to heat the battery in response to determining to heat the battery.

The controller may be configured to obtain information about the maximum charge power from an external server, based on a user input for designating the charger.

The controller may be further configured to estimate the maximum charge power based on the voltage and the current of the battery, measured by the senor for a pre-determined time, when the battery is being charged by the charger.

The controller may be configured to estimate the maximum charge power r based on charge history information of the battery obtained from an external server.

The controller may be further configured to calculate an estimated charge amount of the battery based on the state of charge and a target state of charge and determine a second charge power that is less than or equal to the maximum charge power, based on the estimated charge amount.

The controller may be further configured to calculate an estimated required charge time of the battery, based on the estimated charge amount and determine a third charge power based on the estimated required charge time.

The controller may be further configured to determine whether the battery is chargeable with the first charge power, based on the measured temperature and determine to heat the battery in response to determining that the battery is not chargeable with the fist charge power.

In the battery heating apparatus according to an embodiment disclosed herein, the controller may be further configured to calculate a reference temperature required for charging the battery with the first charge power and determine that the battery is not chargeable with the first charge power, when the measured temperature is less than the reference temperature.

A battery heating method according to an embodiment disclosed herein includes calculating, by a controller, a state of charge (SoC) of a battery, determining, by the controller, a first charge power of the battery based on the state of charge of the battery and a maximum charge power of a charger to charge the battery, measuring, by a sensor, a temperature of the battery, determining, by the controller, whether to heat the battery, based on the first charge power and the measured temperature, and heating, by heater, the battery in response to determining to heat the battery.

The battery heating method according to an embodiment disclosed herein may further include obtaining, by the controller, information about the maximum charge power from an external server, based on a user input for designating the charger.

The battery heating method according to an embodiment disclosed herein may further include estimating, by the controller, the maximum charge power based on a voltage and a current of the battery, measured by the sensor for a pre-determined time, when the battery is being charged by the charger.

The battery heating method further comprises calculating, by the controller, an estimated charge amount of the battery based on the state of charge and a target state of charge and determining, by the controller, a third charge power that is less than or equal to the maximum charge power, based on the estimated charge amount.

The battery heating method further comprises calculating, by the controller, an estimated required charge time of the battery, based on the estimated charge amount and determining, by the controller, a third charge power based on the estimated required charge time.

In the battery heating method according to an embodiment disclosed herein, determining whether to heat the battery may include determining, by the controller, whether the battery is chargeable with the firs charge power, based on the measured temperature and determining, by the controller, to heat the battery in response to determining that the battery is not chargeable with the first charge power.

In the battery heating method according to an embodiment disclosed herein, determining whether the battery is chargeable with the first charge power may include calculating, by the controller, a reference temperature required for charging the battery with the first charge power and determining, by the controller, that the battery is not chargeable with the first charge power, when the measured temperature is less than the reference temperature.

### Advantageous Effects

According to embodiments disclosed herein, the efficiency of power consumption may be improved by determining whether to heat a battery based on various parameters (e.g., a state of charge and a temperature of the battery and a maximum charge power of a charger).

According to embodiments disclosed herein, power consumption caused by unnecessary battery heating may be reduced.

Moreover, various effects recognized directly or indirectly from the disclosure may be provided.

### BRIEF DESCRIPTION OF THE DRAWINGS

FIG. 1 is a block diagram of a battery heating system according to an embodiment.

FIG. 2 is an operating flowchart of a battery heating apparatus according to an embodiment.

FIG. 3 is an operating flowchart of a battery heating apparatus according to an embodiment.

FIG. 4 is an operating flowchart of a battery heating apparatus according to an embodiment.

FIG. 5 is an operating flowchart of a battery heating apparatus according to an embodiment.

### DETAILED DESCRIPTION

Hereinafter, various embodiments of the present disclosure will be disclosed with reference to the accompanying drawings. However, the description is not intended to limit the present disclosure to particular embodiments, and it should be construed as including various modifications, equivalents, and/or alternatives according to the embodiments of the present disclosure.

It should be appreciated that various embodiments of the present document and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. Such terms as “1^{st}”, “2^{nd},” “first”, “second”, “A”, “B”, “(a)”, or “(b)” may be used to simply distinguish a corresponding component from another, and does not limit the components in other aspect (e.g., importance or order), unless mentioned otherwise.

Herein, it is to be understood that when an element (e.g., a first element) is referred to, with or without the term “operatively” or “communicatively”, as “connected with”, “coupled with”, or “linked with”, or “coupled to” or “connected to” to another element (e.g., a second element), it means that the element may be connected with the other element directly (e.g., wiredly), wirelessly, or via a third element.

According to an embodiment of the disclosure, a method according to various embodiments of the disclosure disclosed herein may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store, or between two user devices directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

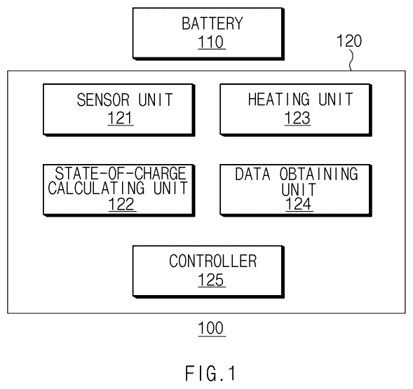

FIG. 1 is a block diagram of a battery heating system according to an embodiment.

Referring to FIG. 1, a battery heating system 100 may include a battery 110 and a battery heating apparatus 120.

The battery heating apparatus 120 may include a sensor unit 121, a state-of-charge calculating unit 122, a heating unit 123, a data obtaining unit 124, and/or a controller 125. According to some embodiments, in the battery heating apparatus 120, at least one of components of FIG. 1 may be omitted or one or more other components may be added.

The sensor unit 121 may be electrically connected to the battery 110. According to an embodiment, the sensor unit 121 may measure a voltage, a current, or a temperature of the battery 110. According to an embodiment, the sensor unit 121 may receive a measurement control signal from the controller 125 to measure the voltage, the current, or the temperature of the battery 110. The sensor unit 121 may measure the voltage, the current, or the temperature of the battery 110 each time when receiving the measurement control signal from the controller 125. According to an embodiment, the sensor unit 121 may transfer a measured voltage value, current value, or temperature value to the state-of-charge calculating unit 122 and/or the controller 125.

The state-of-charge calculating unit 122 may calculate a state of charge (SoC) of the battery 110. According to an embodiment, the state-of-charge calculating unit 122 may calculate a state of charge of the battery 110 based on at least one of the voltage value, the current value, or the temperature value of the battery 110, transferred from the sensor unit 121. According to an embodiment, the state-of-charge calculating unit 122 may transfer the calculated state of charge of the battery 110 to the controller 125.

The heating unit 123 may be a heating means arranged adjacent to the battery 110 to increase the temperature of the battery 110. According to an embodiment, the heating unit 123 may heat the battery 110 each time when receiving a heating control signal from the controller 125.

The data obtaining unit 124 may wiredly or wirelessly receive data from an external device and/or an external server. According to an embodiment, the data obtaining unit 124 may obtain the information about the maximum charge power of the charger to charge the battery 110 or charge history information of the battery 110 from an external server. According to an embodiment, the data obtaining unit 124 may transfer the obtained data to the controller 125.

The controller 125 may be electrically connected to the sensor unit 121, the state-of-charge calculating unit 122, the heating unit 123, and the data obtaining unit 124. According to an embodiment, the controller 125 may execute software to control at least one another component connected to the controller 125 and may process or compute various data. According to an embodiment, the controller 125 may control at least one another component connected to the controller 125 to perform an overall operation of the battery heating apparatus 120. The controller 125 may include at least one of processing devices such as an application specific integrated circuit (ASIC), a digital signal processor (DSP), programmable logic devices (PLD), field programmable gate arrays (FPGAs), a central processing unit (CPU), microcontrollers, or microprocessors.

According to an embodiment, the controller 125 may determine the charge power of the battery 110. Herein, the charge power may mean power to be supplied to the battery 110 from the charger to charge the battery 110. According to an embodiment, the controller 125 may determine the charge power of the battery 110 based on the maximum charge power of the charger to charge the battery 110 and the state of charge of the battery 110.

According to an embodiment, the controller 125 may identify whether there is a user input for designating the charger to charge the battery 110. According to an embodiment, the battery heating apparatus 120 may obtain the user input from an external device through the data obtaining unit 124. According to another embodiment, the battery heating apparatus 120 may include an interface unit for receiving the user input for designating the charger to charge the battery 110.

According to an embodiment, when identifying that there is the user input for designating the charger, the controller 125 may obtain information about the maximum charge power of the charger from the external server. According to an embodiment, the controller 125 may obtain information about the maximum charge power of the charger designated by a user from the external server through the data obtaining unit 124. For example, when identifying that there is a user input for designating a first electric vehicle charging station, the controller 125 may obtain information about a maximum charge power (e.g., 220 kW) of the first electric vehicle charging station from the external server through the data obtaining unit 124.

According to an embodiment, when identifying that there is no user input for designating the charger, the controller 125 may identify whether the battery 110is charged. For example, the controller 125 may identify whether the battery 110 is charged according to whether the battery 110 is electrically connected to the external device. In another example, the controller 125 may identify whether the battery 110 is charged based on a voltage change or a current change of the battery 110.

According to an embodiment, the controller 125 may estimate the maximum charge power of the charger based on a voltage and a current of the battery measured for a designated time, when identifying that the battery 110 is being charged. According to an embodiment, the controller 125 may obtain the charge history information of the battery 110 from the external server through the data obtaining unit 124. In this case, the controller 125 may estimate the maximum charge power of the charger further based on the obtained charge history information.

According to an embodiment, the controller 125 may calculate an estimated charge amount of the battery 110 based on the state of charge and a target state of charge of the battery 110. Herein, the target state of charge may be set based on a charging pattern of a user using the external device including the battery 110, or may be a state of charge preset by the user. The estimated charge amount may mean a difference between the target state of charge and the current state of charge of the battery 110.

According to an embodiment, the controller 125 may calculate an estimated required charge time of the battery 110 based on the estimated charge amount.

According to an embodiment, the controller 125 may determine the charge power of the battery 110 based on the estimated charge amount or the estimated required charge time. According to an embodiment, the controller 125 may determine the charge power of the battery 110 according to the estimated charge amount or the estimated required charge time in a range below the maximum charge power of the charger. For example, the controller 125 may determine the charge power of the battery 110 to be higher for a higher estimated charge amount in the range below the maximum charge power of the charger. In another example, the controller 125 may determine the charge power of the battery 110 to be higher for a longer estimated required charge time in the range below the maximum charge power of the charger.

According to an embodiment, the controller 125 may measure a temperature of the battery 110 through the sensor unit 121.

According to an embodiment, the controller 125 may determine whether to heat the battery 110 based on the temperature of the battery 110. According to an embodiment, the controller 125 may determine whether the battery 110 is chargeable with the determined charge power.

According to an embodiment, the controller 125 may calculate a reference temperature based on the determined charge power of the battery 110. Herein, the reference temperature may be a temperature required for charging the battery 110 with the determined charge power. That is, the reference temperature may be a temperature at which a battery swelling phenomenon occurs when the battery 110 is charged with the determined charge power at a temperature lower than the reference temperature.

According to an embodiment, the controller 125 may identify whether the temperature of the battery 110 is less than the reference temperature.

According to an embodiment, the controller 125 may determine that the battery 110 is not chargeable with the charge power when identifying that the temperature of the battery 110 is less than the reference temperature. In this case, the controller 125 may heat the battery 110. According to an embodiment, the controller 125 may control the heating unit 123 to heat the battery 110.

According to an embodiment, the controller 125 may determine that the battery 110 is chargeable with the charge power when identifying that the temperature of the battery 110 is greater than or equal to the reference temperature. In this case, the controller 125 may not perform battery heating.

As such, the battery heating apparatus 120 may prevent the battery swelling phenomenon by determining whether to heat the battery 110 according to whether the temperature of the battery 110 is less than the reference temperature or greater than or equal to the reference temperature. The reference temperature may be calculated according to the charge power determined based on the state of charge of the battery 110 and the maximum charge power of the charger, thereby minimizing unnecessary battery heating. Thus, the battery heating apparatus 120 may reduce unnecessary power consumption.

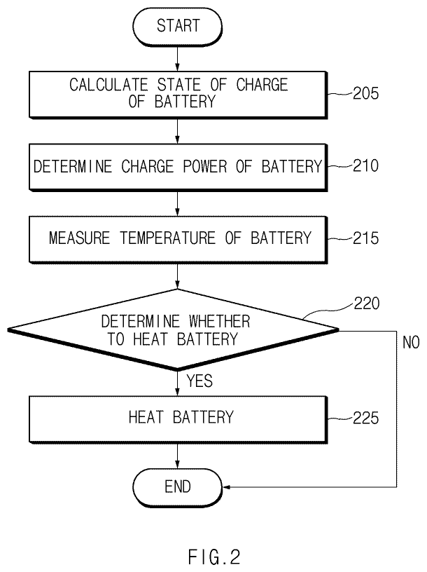

FIG. 2 is an operating flowchart of a battery heating apparatus according to an embodiment. FIG. 2 will be described using components of FIG. 1.

The embodiment shown in FIG. 2 may be an example, and an order of operations according to various embodiments of the present disclosure may be different from that shown in FIG. 2, and some operations shown in FIG. 2 may be omitted, the order of the operations may be changed, or the operations may be merged.

Referring to FIG. 2, in operation 205, the battery heating apparatus 120 may calculate the state of charge of the battery 110. According to an embodiment, the battery heating apparatus 120 may calculate the state of charge of the battery 110 based on at least one of the voltage value, the current value, or the temperature value of the battery 110.

In operation 210, the battery heating apparatus 120 may determine the charge power of the battery 110. Herein, the charge power may mean power to be supplied to the battery 110 from the charger to charge the battery 110. According to an embodiment, the battery heating apparatus 120 may determine the charging power of the battery 110 based on the maximum charging power of the charger to charge the battery 110 and the state of charge of the battery 110, calculated in operation 205. According to an embodiment, the battery heating apparatus 120 may determine the charge power of the battery 110 to be less than or equal to the maximum charge power of the charger. The battery heating apparatus 120 may also determine the charge power of the battery 110 according to the estimated charge amount calculated based on the state of charge of the battery 110. For example, the battery heating apparatus 120 may determine the charge power of the battery 110 to be higher for a higher estimated charge amount.

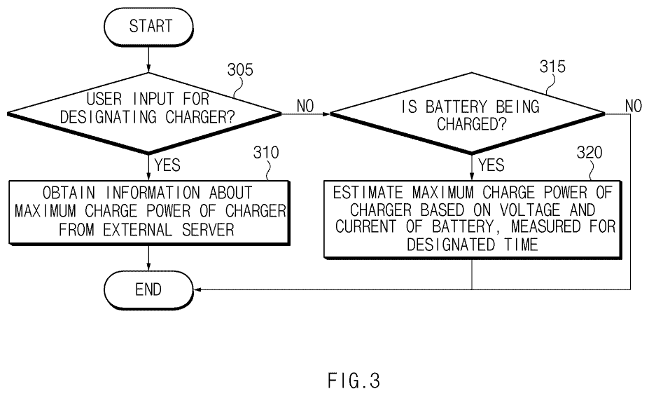

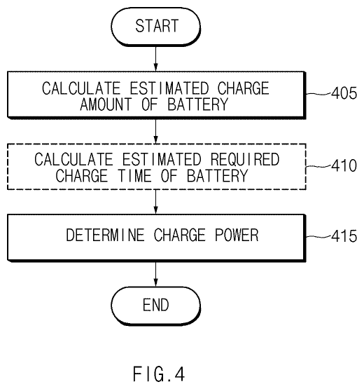

An operation, performed by the battery heating apparatus 120, of obtaining or estimating the maximum charge power of the charger will be described in detail with reference to FIG. 3. In addition, an operation, performed by the battery heating apparatus 120, of determining the charge power will be described in detail with reference to FIG. 4.

In operation 215, the battery heating apparatus 120 may measure the temperature of the battery 110.

In operation 220, the battery heating apparatus 120 may determine whether to heat the battery 110. According to an embodiment, the battery heating apparatus 120 may determine whether to heat the battery 110 based on the temperature of the battery 110, measured in operation 215.

According to an embodiment, the battery heating apparatus 120 may determine whether the battery 110 is chargeable with the charge power determined in operation 210. For example, the battery heating apparatus 120 may determine that the battery 110 is not chargeable with the charge power when the temperature of the battery 110 is less than the reference temperature. Herein, the reference temperature may be a temperature required for charging the battery 110 with the charge power determined in operation 210. That is, the reference temperature may be a temperature at which a battery swelling phenomenon occurs when the battery 110 is charged with the charge power determined in operation 210 at a temperature lower than the reference temperature.

As such, the battery heating apparatus 120 may prevent the battery swelling phenomenon by determining whether to heat the battery 110 according to whether the temperature of the battery 110 is less than the reference temperature or greater than or equal to the reference temperature. The reference temperature may be calculated according to the charge power determined based on the state of charge of the battery 110 and the maximum charge power of the charger, thereby minimizing unnecessary battery heating. Thus, the battery heating apparatus 120 may reduce unnecessary power consumption.

An operation, performed by the battery heating apparatus 120, of determining whether to perform battery heating will be described in detail with reference to FIG. 3.

When determining to heat the battery 110 (‘YES’) in operation 220, the battery heating apparatus 120 may heat the battery 110 in operation 225. According to an embodiment, the battery heating apparatus 120 may control the heating unit 123 to heat the battery 110.

FIG. 3 is an operating flowchart of a battery heating apparatus according to an embodiment. FIG. 3 will be described using components of FIG. 1.

The embodiment shown in FIG. 3 may be an example, and an order of operations according to various embodiments of the present disclosure may be different from that shown in FIG. 3, and some operations shown in FIG. 3 may be omitted, the order of the operations may be changed, or the operations may be merged.

FIG. 3 is a view for describing a method of obtaining or estimating the maximum charge power of the charger to charge the battery 110 among factors required for the battery heating apparatus 120 to determine the charge power in operation 210 of FIG. 2.

Referring to FIG. 3, in operation 305, the battery heating apparatus 120 may identify whether there is a user input for designating the charger to charge the battery 110. According to an embodiment, the battery heating apparatus 120 may obtain a user input made through the external device including the battery 110. According to another embodiment, the battery heating apparatus 120 may include an interface unit for receiving the user input for designating the charger to charge the battery 110. In this case, the battery heating apparatus 120 may perform operation 305 based on the user input received through the interface unit.

When identifying that there is a user input for designating the charger (‘YES’) in operation 305, the battery heating apparatus 120 may obtain the information about the maximum charge power of the charger from the external server in operation 310. According to an embodiment, the battery heating apparatus 120 may obtain the information about the maximum charge power of the charger designated in operation 305 from the external server through the data obtaining unit 124. For example, when identifying that there is a user input for designating a first electric vehicle charging station in operation 305, the battery heating apparatus 120 may obtain information about a maximum charge power (e.g., 220 kW) of the first electric vehicle charging station from the external server through the data obtaining unit 124.

When identifying that there is no user input for designating the charger (‘NO’) in operation 305, the battery heating apparatus 120 may identify whether the battery 110 is charged in operation 315. For example, the battery heating apparatus 120 may identify whether the battery 110 is charged according to whether the battery 110 is electrically connected to the external device. In another example, the battery heating apparatus 120 may identify whether the battery 110 is charged based on a voltage change or a current change of the battery 110.

When identifying that the battery 110 is not being charged (‘NO’) in operation 315, the battery heating apparatus 120 may terminate an operation corresponding to FIG. 3.

When identifying that the battery 110 is being charged (‘YES’) in operation 315, the battery heating apparatus 120 may estimate the maximum charge power of the charger based on the voltage and the current of the battery, measured for a designated time, in operation 320. According to an embodiment, the battery heating apparatus 120 may obtain the charge history information of the battery 110 from the external server. In this case, the battery heating apparatus 120 may estimate the maximum charge power of the charger further based on the obtained charge history information.

FIG. 4 is an operating flowchart of a battery heating apparatus according to an embodiment. FIG. 4 will be described using components of FIG. 1.

The embodiment shown in FIG. 4 may be an example, and an order of operations according to various embodiments of the present disclosure may be different from that shown in FIG. 4, and some operations shown in FIG. 4 may be omitted, the order of the operations may be changed, or the operations may be merged. For example, operation 410 may be omitted from FIG. 4.

FIG. 4 is a view for describing in detail a method, performed by the battery heating apparatus 120, of determining the charge power in operation 210 of FIG. 2.

Referring to FIG. 4, in operation 405, the battery heating apparatus 120 may calculate an estimated charge amount of the battery 110. According to an embodiment, the battery heating apparatus 120 may calculate the estimated charge amount of the battery 110 based on the state of charge, calculated in operation 205 of FIG. 2, and a target state of charge of the battery 110. Herein, the target state of charge may be set based on a charging pattern of a user using the external device including the battery 110, or may be a state of charge preset by the user. The estimated charge amount may mean a difference between the target state of charge and the state of charge calculated in operation 205.

In operation 410, the battery heating apparatus 120 may calculate an estimated required charge time of the battery 110. According to an embodiment, the battery heating apparatus 120 may calculate the estimated required charge time of the battery 110 based on the estimated charge amount calculated in operation 405.

In operation 415, the battery heating apparatus 120 may determine the charge power of the battery 110. Herein, the charge power may mean power to be supplied to the battery 110 from the charger to charge the battery 110. According to an embodiment, the battery heating apparatus 120 may determine the charge power of the battery 110 based on the estimated charge amount calculated in operation 405 or the estimated required charge time calculated in operation 410.

According to an embodiment, the battery heating apparatus 120 may determine the charge power of the battery 110 according to the estimated charge amount or the estimated required charge time in a range below the maximum charge power of the charger. For example, the battery heating apparatus 120 may determine the charge power of the battery 110 to be higher for a higher estimated charge amount in the range below the maximum charge power of the charger. In another example, the battery heating apparatus 120 may determine the charge power of the battery 110 to be higher for a longer estimated required charge time in the range below the maximum charge power of the charger.

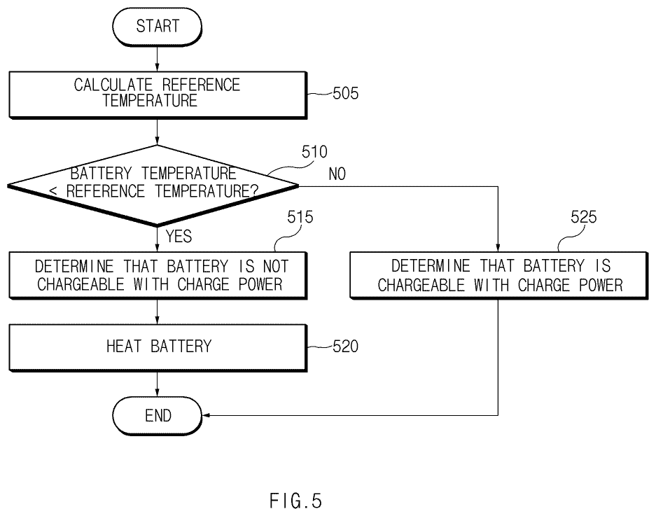

FIG. 5 is an operating flowchart of a battery heating apparatus according to an embodiment. FIG. 5 will be described using components of FIG. 1.

The embodiment shown in FIG. 5 may be an example, and an order of operations according to various embodiments of the present disclosure may be different from that shown in FIG. 5, and some operations shown in FIG. 5 may be omitted, the order of the operations may be changed, or the operations may be merged.

FIG. 5 is a view for describing in detail operations 220 and 225 of FIG. 2 where the battery heating apparatus 120 determines whether to perform battery heating and performs battery heating.

Referring to FIG. 5, in operation 505, the battery heating apparatus 120 may calculate a reference temperature. According to an embodiment, the battery heating apparatus 120 may calculate the reference temperature based on the charge power determined in operation 210 of FIG. 2. Herein, the reference temperature may be a temperature required for charging the battery 110 with the charge power determined in operation 210 of FIG. 2. That is, the reference temperature may be a temperature at which a battery swelling phenomenon occurs when the battery 110 is charged with the charge power determined in operation 210 at a temperature lower than the reference temperature.

In operation 510, the battery heating apparatus 120 may identify whether the temperature of the battery 110 measured in operation 215 of FIG. 2 is less than the reference temperature calculated in operation 505.

When identifying that the temperature of the battery 110 is less than the reference temperature (‘YES’) in operation 510, the battery heating apparatus 120 may determine that the battery 110 is not chargeable with the charge power in operation 515.

In operation 520, the battery heating apparatus 120 may heat the battery 110. According to an embodiment, the battery heating apparatus 120 may control the heating unit 123 to heat the battery 110.

When identifying that the temperature of the battery 110 is greater than or equal to the reference temperature (‘NO’) in operation 510, the battery heating apparatus 120 may determine that the battery 110 is chargeable with the charge power in operation 525. In this case, the battery heating apparatus 120 may not perform battery heating.

As such, the battery heating apparatus 120 may prevent the battery swelling phenomenon by determining whether to heat the battery 110 according to whether the temperature of the battery 110 is less than the reference temperature or greater than or equal to the reference temperature. The reference temperature may be calculated according to the charge power determined based on the state of charge of the battery 110 and the maximum charge power of the charger, thereby minimizing unnecessary battery heating. Thus, the battery heating apparatus 120 may reduce unnecessary power consumption.

Terms such as “include”, “constitute” or “have” described above may mean that the corresponding component may be inherent unless otherwise stated, and thus should be construed as further including other components rather than excluding other components. All terms including technical or scientific terms have the same meanings as those generally understood by those of ordinary skill in the art to which the embodiments disclosed herein pertain, unless defined otherwise. The terms used generally like terms defined in dictionaries should be interpreted as having meanings that are the same as the contextual meanings of the relevant technology and should not be interpreted as having ideal or excessively formal meanings unless they are clearly defined in the present document.

1. A battery heating apparatus comprising:
one or more sensors configured to measure at least one of a voltage, a current, or a temperature of the battery;
a controller configured to:
determine a first charge power of the battery based on calculated state of charge (SoC) of the battery and a maximum charge power of a charger to charge the battery; and
determine whether to heat the battery based on the measured temperature and the first charge power; and
a heater configured to heat the battery in response to determining to heat the battery.

2. The battery heating apparatus of claim 1, wherein the controller is further configured to obtain information about the maximum charge power from an external server, based on a user input for designating the charger.

3. The battery heating apparatus of claim 1, wherein the controller is further configured to estimate the maximum charge power based on the voltage and the current of the battery, measured by the sensor for a pre-determined time, when the battery is being charged by the charger.

4. The battery heating apparatus of claim 3, wherein the controller is further configured to
estimate the maximum charge power based on charge history information of the battery obtained from an external server.

5. The battery heating apparatus of claim 1, wherein the controller is further configured to:
calculate an estimated charge amount of the battery based on the state of charge and a target state of charge; and
determine a second charge power that is less than or equal to the maximum charge power, based on the estimated charge amount.

6. The battery heating apparatus of claim 5, wherein the controller is further configured to:
calculate an estimated required charge time of the battery, based on the estimated charge amount; and
determine a third charge power based on the estimated required charge time.

7. The battery heating apparatus of claim 1, wherein the controller is further configured to:
determine whether the battery is chargeable with the first charge power, based on the measured temperature; and
determine to heat the battery in response to determining that the battery is not chargeable with the first charge power.

8. The battery heating apparatus of claim 1, wherein the controller is further configured to:
calculate a reference temperature required for charging the battery with the first charge power; and
determine that the battery is not chargeable with the first charge power, when the measured temperature is less than the reference temperature.

9. A battery heating method comprising:
calculating, by a controller, a state of charge (SoC) of a battery;
determining, by the controller, a first charge power of the battery based on the state of charge of the battery and a maximum charge power of a charger to charge the battery;
measuring, by a sensor, a temperature of the battery;
determining, by the controller, whether to heat the battery, based on the first charge power and the measured temperature; and
heating, by a heater, the battery in response to determining to heat the battery.

10. The battery heating method of claim 9, further comprising obtaining, by the controller, information about the maximum charge power from an external server, based on a user input for designating the charger.

11. The battery heating method of claim 9, further comprising estimating, by the controller, the maximum charge power based on a voltage and a current of the battery, measured by the sensor for a pre-determined time when the battery is being charged by the charger.

12. The battery heating method of claim 9, further comprising:
calculating, by the controller, an estimated charge amount of the battery based on the state of charge and a target state of charge; and
determining, by the controller, a second charge power that is less than or equal to the maximum charge power, based on the estimated charge amount.

13. The battery heating method of claim 9, further comprising:
calculating, by the controller, an estimated required charge time of the battery, based on the estimated charge amount; and
determining, by the controller, a third charge power based on the estimated required charge time.

14. The battery heating method of claim 9, wherein determining whether to heat the battery comprises:
determining, by the controller, whether the battery is chargeable with the first charge power, based on the measured temperature; and
determining, by the controller, to heat the battery in response to determining that the battery is not chargeable with the first charge power.

15. The battery heating method of claim 14, wherein determining whether the battery is chargeable with the first charge power comprises:
calculating, by the controller, a reference temperature required for charging the battery with the first charge power; and
determining, by the controller, that the battery is not chargeable with the first charge power, when the measured temperature is less than the reference temperature.
